(19) United States
(12) Patent Application Publication
(10) Pub. No.: US 2025/0048722 A1
(43) Pub. Date: Feb. 6, 2025

(54) SEMICONDUCTOR DEVICE

(71) Applicant: ROHM CO., LTD., Kyoto (JP)

(72) Inventors: Shoji TAKEI, Kyoto (JP); Yuji KOGA, Kyoto (JP)

(73) Assignee: ROHM CO., LTD., Kyoto (JP)

(21) Appl. No.: 18/789,406

(22) Filed: Jul. 30, 2024

(30) Foreign Application Priority Data
Aug. 3, 2023 (JP) 2023-127278

(51) Int. Cl. H01L 29/78; H01L 29/423; H01L 29/66

(52) U.S. Cl. CPC H01L 29/7818; H01L 29/42376; H01L 29/66696

(57) ABSTRACT

The present disclosure provides a semiconductor device including a diode. The semiconductor device includes: a semiconductor substrate; an n-type diffusion region selectively formed in a surface layer portion of a p-type epitaxial layer; an n-type buried layer sandwiched between the semiconductor substrate and the n-type diffusion region and having an impurity concentration greater than that of the n-type diffusion region; a p-type anode contact region formed in a surface layer portion of a first main surface of the semiconductor substrate; an n-type first cathode contact region formed in a surface layer portion of the n-type diffusion region and in a surface layer portion of the first main surface; a p-type well region extending along a depth direction from the first main surface outside the first cathode contact region to reach the n-type buried layer, dividing the n-type diffusion region along a direction along the first main surface.

### TECHNICAL FIELD

The present disclosure relates to a semiconductor device.

### BACKGROUND

Patent publication 1 discloses a diode including a P-type semiconductor substrate, an n-type epitaxial layer formed on a surface of the p-type semiconductor substrate, and an n-type buried layer formed in a border portion between the p-type semiconductor substrate and the n-type epitaxial layer.

### PRIOR ART DOCUMENT

### Patent Publication

[Patent document 1] Japan Patent Publication No. 2015-115365

### BRIEF DESCRIPTION OF THE DRAWINGS

FIG. 1 is a schematic plan view of a semiconductor device according to a first embodiment of the present disclosure.

FIG. 2 is a diagram of an example of a planar layout of an impurity diffusion region in a diode region.

FIG. 3 is a diagram of an example of a planar shape of a field insulating film in the diode region.

FIG. 4 is a diagram of an example of a planar shape of a gate electrode in the diode region.

FIG. 5 is a cross-sectional diagram along a section line V-V in FIG. 4.

FIG. 6 is an enlarged diagram of a part surrounded by the dotted line VI in FIG. 5.

FIG. 7A is a diagram of a part of manufacturing step for the semiconductor device, and is a diagram corresponding to FIG. 6.

FIG. 7B is a diagram of a next step of that in FIG. 7A.

FIG. 7C is a diagram of a next step of that in FIG. 7B.

FIG. 7D is a diagram of a next step of that in FIG. 7C.

FIG. 7E is a diagram of a next step of that in FIG. 7D.

FIG. 7F is a diagram of a next step of that in FIG. 7E.

FIG. 7G is a diagram of a next step of that in FIG. 7F.

FIG. 7H is a diagram of a next step of that in FIG. 7G.

FIG. 7I is a diagram of a next step of that in FIG. 7H.

FIG. 7J is a diagram of a next step of that in FIG. 7I.

FIG. 7K is a diagram of a next step of that in FIG. 7J.

FIG. 7L is a diagram of a next step of that in FIG. 7K.

FIG. 7M is a diagram of a next step of that in FIG. 7L.

FIG. 8 is a circuit diagram of a configuration of a signal output circuit applying the semiconductor device.

FIG. 9 is a schematic plan view of a semiconductor device according to a second embodiment of the present disclosure, and is a diagram corresponding to FIG. 6.

### DETAILED DESCRIPTION OF THE EMBODIMENTS

### Detailed Description

Details of embodiments of the present disclosure are given with the accompanying drawings below.

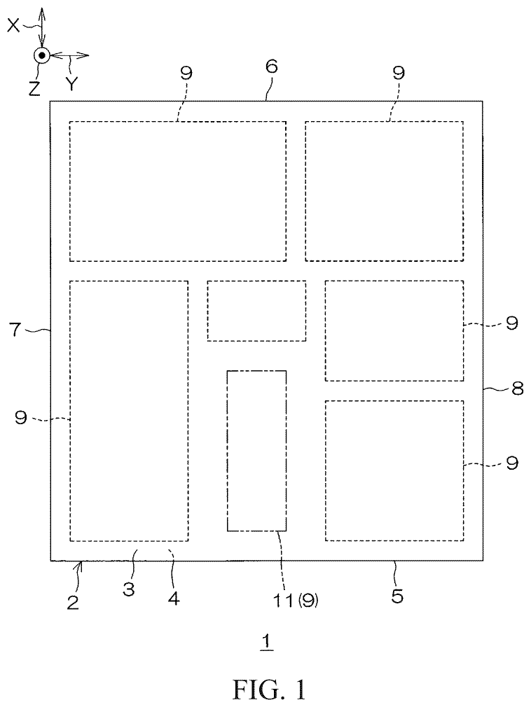

FIG. 1 shows a schematic plan view of a semiconductor device 1 according to a first embodiment of the present disclosure.

The semiconductor device 1 includes a semiconductor chip 2 having a cuboid shape. The semiconductor chip 2 forms the shape of the semiconductor device 1, for example, a structural body formed of a monocrystalline semiconductor material in a chip shape (a cuboid shape). The semiconductor chip 2 is formed of a semiconductor material such as Si or SiC. The semiconductor chip 2 has a first main surface 3 on one side, a second main surface 4 on the other side, and first to fourth side surfaces 5 to 8 connecting the first main surface 3 and the second main surface 4. The first to fourth side surfaces 5 to 8 include a first side surface 5, a second side surface 6, a third side surface 7 and a fourth side surface 8. The third side surface 7 and the fourth side surface 8 extend along a first direction X, and face a second direction Y perpendicular to the first direction X. The first side surface 5 and the second side surface 6 extend along the second direction Y, and face the first direction X.

The first main surface 3 and the second main surface 4 form a quadrilateral shape in a plan view of viewing from a third direction Z (a normal direction of the first main surface 3 and the second main surface 4) (to be referred to as “in the plan view” below). The first main surface 3 can be referred to as a device surface on which functional devices are formed. The second main surface 4 can be referred to as a non-device surface on which no functional device is formed. Multiple device regions 9 are formed on the first main surface 3. The number and configuration of the multiple device regions 9 can be any as desired. The multiple device regions 9 can also include functional devices formed using a surface portion of the first main surface 3. The functional devices can include, for example, at least one of semiconductor switch devices, semiconductor rectifier devices and passive devices. The functional devices can also include a circuit network formed by a combination of at least two of a semiconductor switch device, a semiconductor rectifier device and a passive device.

The semiconductor switch devices can include, for example, at least one of a metal oxide semiconductor field effect transistor (MOSFET), a bipolar junction transistor (BJT), an insulated gate bipolar junction transistor (IGBT), and a junction field effect transistor (JFET). The semiconductor rectifier devices can include, for example, at least one of a pn junction diode, a pin junction diode, a Zener diode, a Schottky diode and a fast recovery diode. The passive devices can include, for example, at least one of a resistor, a capacitor and an inductor.

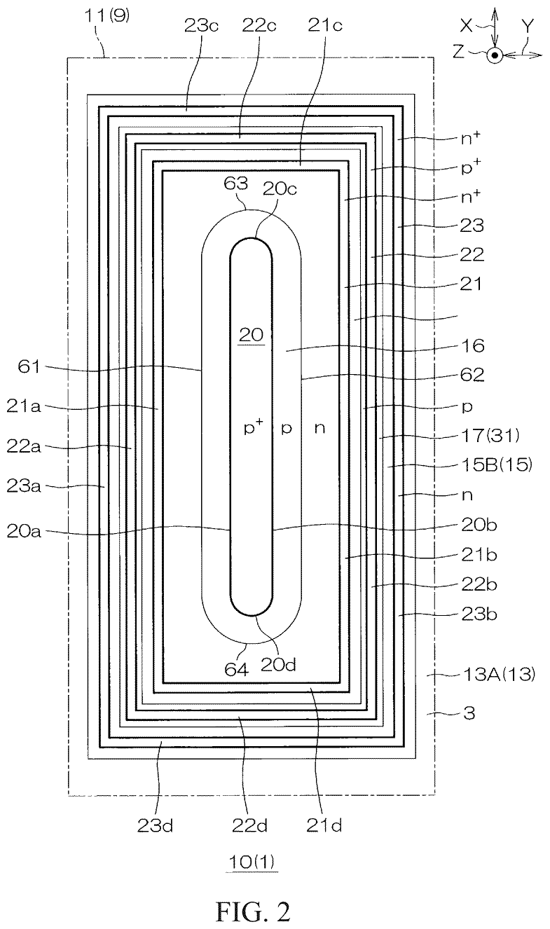

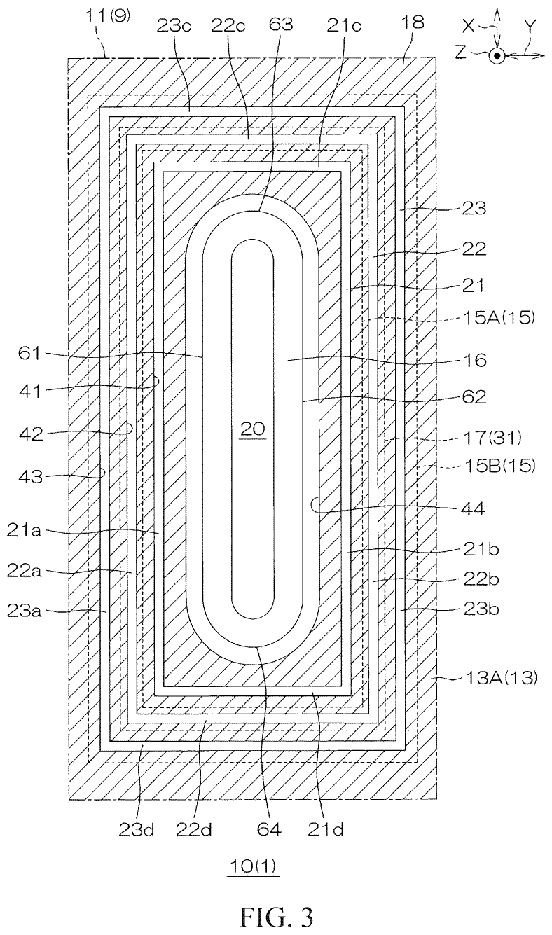

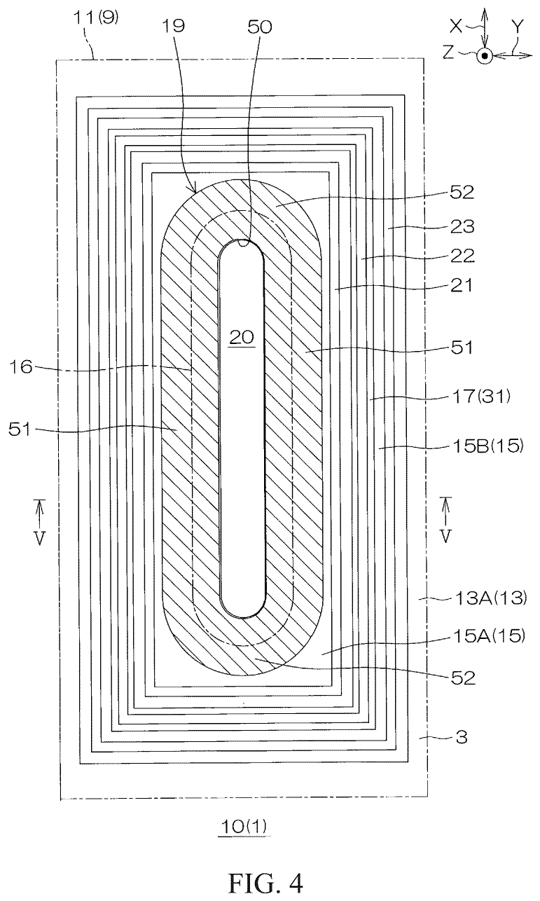

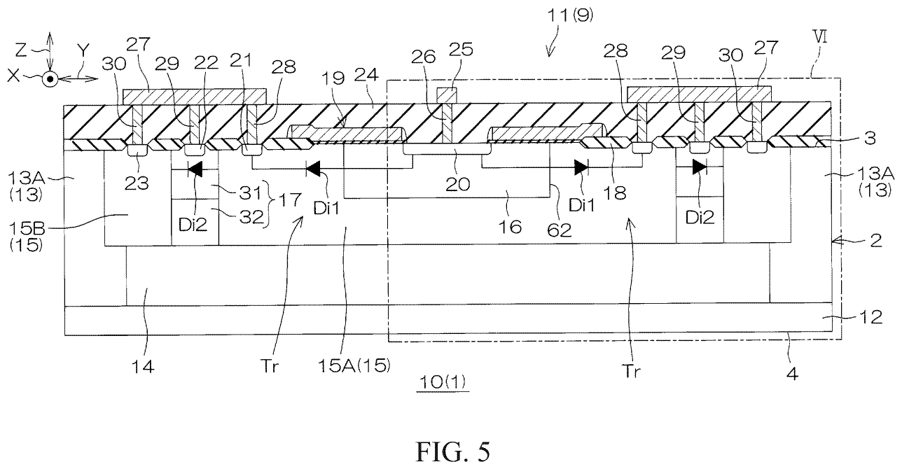

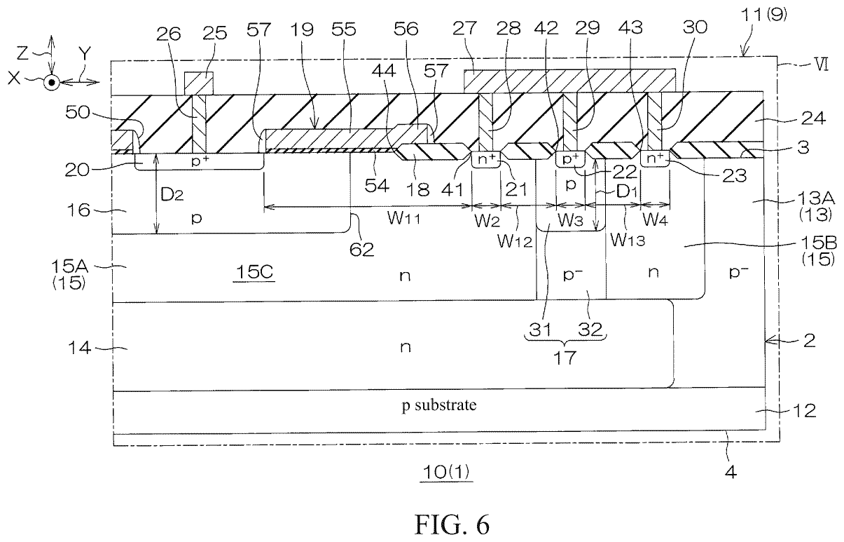

FIG. 2 shows a diagram of an example of a planar layout of an impurity diffusion region in a diode region 11. FIG. 3 shows a diagram of an example of a planar shape of a field insulating film 18 in the diode region 11. FIG. 4 shows a diagram of an example of a planar shape of a gate electrode 19 in the diode region 11. FIG. 5 shows a cross-sectional diagram along a section line V-V in FIG. 4. FIG. 6 shows an enlarged diagram of a part surrounded by the dotted line VI in FIG. 5. Referring to FIG. 1 to FIG. 6, the structure of the diode region 11 in which a diode 10 is formed as an example of a functional device in the multiple device regions 9 is specifically described below. The diode 10 has a laterally diffused metal oxide semiconductor (LDMOS) transistor structure. The diode 10 is a pn junction diode.

Referring to FIG. 5 and FIG. 6, the diode 10 includes a semiconductor substrate 12 and a semiconductor layer 13. The semiconductor substrate 12 is a p-type (a first conductivity) semiconductor substrate. More specifically, the semiconductor substrate 12 is a Si substrate. The semiconductor substrate 12 is formed in a surface portion of the second main surface 4 of the semiconductor chip 2. A p-type impurity concentration of the semiconductor substrate 12 can be between about 1.0×10¹³ cm⁻³ and about 1.0×10¹⁵ cm⁻³. A thickness of the semiconductor substrate 12 can be, for example, between about 100 μm and about 500 μm. Since the semiconductor substrate 12 has a lower p-type impurity concentration, it can also be referred to as a p-type region.

Referring to FIG. 2, FIG. 5 and FIG. 6, a semiconductor layer 13 is formed on the semiconductor substrate 12. The semiconductor layer 13 is formed in a surface portion of the first main surface 3 of the semiconductor chip 2. The semiconductor layer 13 is formed in an entire region of the surface portion of the first main surface 3, and is exposed from the first main surface 3 and the first to fourth side surfaces 5 to 8 (referring to FIG. 1). A thickness of the semiconductor layer 13 can be, for example, less than the thickness of the semiconductor substrate 12. The thickness of the semiconductor layer 13 can be, for example, between about 5 μm and about 20 km.

Referring to FIG. 2, FIG. 5 and FIG. 6, the semiconductor layer 13 includes a p-type epitaxial layer 13A. As shown in FIG. 5 and FIG. 6, the p-type epitaxial layer 13A is selectively formed in the surface portion of the first main surface 3 of the semiconductor chip 2. An n-type diffusion region 15 is formed on the p-type epitaxial layer 13A. The n-type diffusion region 15 is formed to have a quadrilateral shape extending longer in the first direction X in the plan view. The p-type epitaxial layer 13A is formed to have a quadrilateral annular shape surrounding sides of the n-type diffusion region 15.

A p-type impurity concentration of the p-type epitaxial layer 13A can be between about 1.0×10¹³ cm⁻³ and about 1.0×10¹⁵ cm⁻³. The p-type impurity of the p-type epitaxial layer 13A can be equal to the p-type impurity concentration of the semiconductor layer 12. In the surface portion of the first main surface 3, the p-type epitaxial layer 13A is formed in a region apart from a region in which the n-type diffusion region 15 is formed, and is exposed from the first main surface 3 and the first to fourth side surfaces 5 to 8 (referring to FIG. 1).

Referring to FIG. 5 and FIG. 6, the semiconductor layer 13 is separated into multiple regions by an element separation structure (not shown, for example, an element separation well, a deep trench isolation (DTI), or a shallow trench isolation (STI)). The element separation structure divides the semiconductor chip 2 into the multiple device regions 9. FIG. 2 to FIG. 6 depict the device region 9 in which the diode region 11 is formed among the separated multiple device regions 9. Referring to FIG. 2, in the diode region 11, the n-type diffusion region 15 is formed in a center portion of the first main surface 3, and the p-type epitaxial layer 13A is formed in a peripheral portion of the first main surface 3.

Referring to FIG. 2, FIG. 5 and FIG. 6, the n-type diffusion region 15 is selectively formed in the surface portion of the first main surface 3 of the semiconductor chip 2. The n-type diffusion region 15 extends as a layer along the first main surface 3. A depth of the n-type diffusion region 15 is the same throughout the entire circumferential region. An n-type impurity concentration of the n-type diffusion region 15 can be between about 1.0×10¹² cm⁻³ and about 1.0×10¹³ cm⁻³. A thickness of the n-type diffusion region 15 can be between about 5 μm and about 20 μm. The n-type diffusion region 15 overlaps an n-type buried layer 14 described below in the plan view. A bottom of the n-type diffusion region 15 is in contact with the n-type buried layer 14.

Referring to FIG. 2, FIG. 5 and FIG. 6, the diode 10 further includes the n-type buried layer 14 (a buried layer of a second conductivity type), a p-type well region (a well region of a first conductivity type) 16, a p-type layer (a region of the first conductivity type) 17, a field insulating film 18, a gate electrode 19, an anode contact region 20, a first cathode contact region 21, a second cathode contact region 22, a third cathode contact region 23, an interlayer insulating film 24, an anode wiring 25, an anode contact 26, a cathode wiring 27, a first cathode contact 28, a second cathode contact 29 and a third cathode contact 30. As shown in FIG. 6, the p-type layer 17 includes an upper p-type layer 31 and a lower p-type layer 32.

Referring to FIG. 5 and FIG. 6, the n-type buried layer 14 is an n-type (the second conductivity type) layer (B/L) buried between the semiconductor substrate 12 and the semiconductor layer 13. More specifically, the n-type buried layer 14 extends as a layer along the first main surface 3 to cross a border between the semiconductor substrate 12 and the n-type diffusion region 15. That is to say, the n-type buried layer 14 is sandwiched by the semiconductor substrate 12 and the n-type diffusion region 15. Although omitted from the drawings, the n-type buried layer 14 has a quadrilateral shape in the plan view. The n-type buried layer 14 is electrically connected to the semiconductor substrate 12 and the p-type epitaxial layer 13A. A thickness of the n-type buried layer 14 can be between about 0.1 μm and about 5 μm. An n-type impurity concentration of the n-type buried layer 14 can be between about 1.0×10¹³ cm⁻³ and about 1.0×10¹⁴ cm⁻³.

The n-type impurity concentration of the n-type buried layer 14 is greater than the n-type impurity concentration of the n-type diffusion region 15. More specifically, as described above, alternatively, the n-type impurity concentration of the n-type buried layer 14 can be between about 1.0×10¹³ cm⁻³ and about 1.0×10¹⁴ cm⁻³, and the n-type impurity concentration of the n-type diffusion region 15 can be between about 1.0×10¹² cm⁻³ and about 1.0×10¹³ cm⁻³. The n-type impurity concentration of the n-type buried layer 14 can be 10 times greater than the n-type impurity concentration of the n-type diffusion region 15. The n-type impurity concentration of the n-type buried layer 14 can be 1 time greater than the n-type impurity concentration of the n-type diffusion region 15.

The n-type diffusion region 15 is divided into an inner diffusion region 15A having a quadrilateral shape in the plan view and an outer diffusion region 15B having a quadrilateral annular shape in the plan view. An outer periphery of the inner diffusion region 15A and an inner peripheral of the outer diffusion region 15B are separated along the first direction X and the second direction Y, respectively. The inner diffusion region 15A includes a lower diffusion region 15C sandwiched between the n-type buried layer 14 and the p-type well region 16.

Referring to FIG. 2, FIG. 5 and FIG. 6, the p-type well region 16 is a p-type diffusion region formed in a surface portion of the n-type diffusion region 15. The p-type well region 16 is in contact with the inner diffusion region 15A (the n-type diffusion region 15) in both of the first direction X and the second direction Y. The p-type well region 16 is in contact with the lower diffusion region 15C (the inner diffusion region 15A) in the third direction Z. The p-type well region 16 is a region to which a voltage is applied from the anode wiring 25 in the diode region 11.

Referring to FIG. 2 and FIG. 5, the p-type well region 16 is formed to have an ellipsoidal shape extending longer in the first direction X in the plan view. The p-type well region 16 has a first peripheral edge 61 and a second peripheral edge 62 extending linearly along the first direction X with a space in between. The p-type well region 16 has a third peripheral edge 63 and a fourth peripheral edge 64 connecting the first peripheral edge 61 and the second peripheral edge 62. The third peripheral edge 63 and the fourth peripheral edge 64 face each other in the X direction. The third peripheral edge 63 and the fourth peripheral edge 64 are formed as arcs expanding outward in the first direction X.

Referring to FIG. 2 and FIG. 5, the p-type layer 17 is a p-type impurity region formed in the surface portion of the first main surface 3. A lower end of the p-type layer 17 reaches the n-type buried layer 14. The p-type layer 17 has an annular shape in the plan view, and divides the n-type diffusion region 15 in both of the first direction X and the second direction Y. A depth of the p-type layer 17 is the same throughout the entire circumferential region. Referring to FIG. 2, the p-type layer 17 can also be formed to have a quadrilateral annular shape extending longer in the first direction X in the plan view.

The p-type layer 17 is adjacent to the inner diffusion region 15A to surround the outer periphery of the inner diffusion region 15A in the plan view. The p-type layer 17 is adjacent to the outer diffusion region 15B to surround the inner periphery of the outer diffusion region 15B in the plan view. The p-type layer 17 surrounds an outer periphery of the p-type well region 16 in the plan view. The p-type layer 17 is formed to have a space from the p-type well region 16 in both of the first direction X and the second direction Y. Although omitted from the drawings, the p-type layer 17 can also be formed to have an ellipsoidal shape extending longer in the first direction X in the plan view.

Referring to FIG. 6, the p-type layer 17 includes an upper p-type layer 31 and a lower p-type layer 32. The upper p-type layer 31 and the lower p-type layer 32 are vertically adjacent. The upper p-type layer 31 and the lower p-type layer 32 form the annular p-type layer 17.

The upper p-type layer 31 is a p-type impurity region formed in the surface portion of the first main surface 3. The upper p-type layer 31 is formed by a p-type diffusion layer. A p-type impurity concentration of the upper p-type layer 31 can be, for example, between about 1.0×10¹⁶ cm⁻³ and about 5.0×10¹⁷ cm⁻³. The p-type impurity concentration of the upper p-type layer 31 can be equal to the p-type impurity concentration of the p-type well region 16. The p-type impurity concentration of the upper p-type layer 31 can be greater than the p-type impurity concentration of the p-type well region 16. The p-type impurity concentration of the upper p-type layer 31 can be less than the p-type impurity concentration of the p-type well region 16.

Referring to FIG. 2, the upper p-type layer 31 has, for example, a quadrilateral annular shape. The upper p-type layer 31 surrounds sides of the p-type well region 16. The upper p-type layer 31 faces the p-type well region 16 in both of the first direction X and the second direction Y. A first depth D₁ of a bottom of the upper p-type layer 31 is equal to a second depth D₂ of a bottom of the p-type well region 16. The first depth D₁ can also be greater than the second depth D₂. The first depth D₁ can also be less than the second depth D₂.

Referring to FIG. 5 and FIG. 6, the lower p-type layer 32 is formed on the side of the second main surface 4 relative to the upper p-type layer 31. The lower p-type layer 32 is in contact with the upper p-type layer 31. Although omitted from the drawings, the lower p-type layer 32 has a quadrilateral shape overlapping the p-type layer 31 in the plan view. The lower p-type layer 32 does not face the p-type well region 16 in a horizontal direction (either of the first direction X and the second direction Y).

The lower p-type layer 32 is formed by a p-type epitaxial layer. A p-type impurity concentration of the lower p-type layer 32 can be, for example, between about 1.0×10¹³ cm⁻³ and about 1.0×10¹⁵ cm⁻³. The p-type impurity of the lower p-type layer 32 can be equal to the p-type impurity concentration of the p-type epitaxial layer 13A. The p-type impurity concentration of the lower p-type layer 32 can be equal to the p-type impurity concentration of the semiconductor substrate 12. The p-type impurity concentration of the lower p-type layer 32 is less than the p-type impurity concentration of the upper p-type layer 31. The p-type impurity concentration of the lower p-type layer 32 is less than the p-type impurity concentration of the p-type well region 16. Since the lower p-type layer 32 has a lower p-type impurity concentration, it can also be referred to as a p-type region.

Referring to FIG. 6, an inner peripheral end of the upper p-type layer 31 and an inner peripheral end of the lower p-type layer 32 are aligned in both of the first direction X and the second direction Y, and an outer peripheral end of the upper p-type layer 31 and an outer peripheral end of the lower p-type layer 32 are aligned in both of the first direction X and the second direction Y. Although omitted from the drawings, the inner peripheral end of the upper p-type layer 31 can be spaced outward or can be spaced inward relative to the inner peripheral end of the lower p-type layer 32. Moreover, although omitted from the drawings, the outer peripheral end of the upper p-type layer 31 can be spaced outward or can be spaced inward relative to the outer peripheral end of the lower p-type layer 32.

Referring to FIG. 2 and FIG. 3, the field insulating film 18 is formed on the first main surface 3 of the semiconductor chip 2. The field insulating film 18 covers the first main surface 3. For the sake of clarity, in FIG. 2, outer edges of the anode contact region 20, the first cathode contact region 21, the second cathode contact region 22 and the third cathode contact region 23 are all indicated by bold solid lines. Moreover, for the sake of clarity, in FIG. 3, the field insulating film 18 is indicated by shading lines. A region without the shading lines in FIG. 3 is a region not covered by the field insulating film 18. The field insulating film 18 can also be, for example, a local oxidation of silicon (LOCOS) film, which is formed by selectively oxidizing a surface of the n-type diffusion region 15 (the first main surface 3).

Referring to FIG. 3, the field insulating film 18 has a first opening portion 41, a second opening portion 42, a third opening portion 43 and a fourth opening portion 44. The first opening portion 41 is formed to have a quadrilateral annular shape extending longer in the first direction X in the plan view. The first opening portion 41 exposes a portion (to be referred to as the first cathode contact region 21 below) of the inner diffusion region 15A of the n-type diffusion region 15. The second opening portion 42 is formed to extend longer in the first direction X, and is formed to have a quadrilateral annular shape surrounding the first opening portion 41 in the plan view. The second opening portion 42 exposes a portion (to be referred to as the second cathode contact region 22 below) of the upper p-type layer 31 (the p-type layer 17). The third opening portion 43 is formed to extend longer in the first direction X, and is formed to have a quadrilateral annular shape surrounding the first opening portion 41 in the plan view. The third opening portion 43 exposes a portion (to be referred to as the third cathode contact region 23 below) of the outer diffusion region 15B of the n-type diffusion region 15.

Referring to FIG. 3, the fourth opening portion 44 is formed to have an ellipsoidal annular shape extending longer in the first direction X in the plan view. The fourth opening portion 44 exposed the inner diffusion region 15A (the n-type diffusion region 15) and the p-type well region 16. An opening width (a width in the second direction Y) of the fourth opening portion 44 is greater than opening widths (widths in the first direction X and the second direction Y) of the first opening portion 41, the second opening portion 42 and the third opening portion 43. Although omitted from the drawings, the fourth opening portion 44 can also be formed to have a quadrilateral shape extending longer in the first direction X in the plan view.

Although omitted from the drawings, the first opening portion 41 can also be formed in pair to sandwich the fourth opening portion 44 in the second direction Y. Moreover, although omitted from the drawings, the second opening portion 42 can also be formed in pair to sandwich the first opening portion 41 and the fourth opening portion 44 in the second direction Y. Moreover, although omitted from the drawings, the third opening portion 43 can also be formed in pair to sandwich the first opening portion 41, the second opening portion 42 and the fourth opening portion 44 in the second direction Y.

Referring to FIG. 2, FIG. 5 and FIG. 6, the first cathode contact region 21 is formed in a surface portion of the inner diffusion region 15A. The first cathode contact region 21 can have an n-type impurity concentration greater than an n-type impurity concentration of the inner diffusion region 15A. The n-type impurity concentration of the first cathode contact region 21 can also be, for example, between about 1.0×10¹⁶ cm⁻³ and about 5.0×10¹⁷ cm⁻³.

Referring to FIG. 3, the first cathode contact region 21 is exposed from the field insulating film 18 in the first opening portion 41. The first cathode contact region 21 has a quadrilateral annular shape matching the first opening portion 41. The first cathode contact region 21 includes a first side portion 21a and a second side portion 21b extending along the first direction X with a space in between. The first cathode contact region 21 further includes a third side portion 21c and a fourth side portion 21d connecting the first side portion 21a and the second side portion 21b. The third side portion 21c and the fourth side portion 21d extend along the second direction Y with a space in between. Referring to FIG. 6, a first width W₁ of the first cathode contact region 21 can be between about 0.6 μm and about 0.8 μm. The first width W₁ can be constant in an entire circumferential region of the first cathode contact region 21.

Referring to FIG. 2, FIG. 5 and FIG. 6, the second cathode contact region 22 is formed in a surface portion of the upper p-type layer 31 (the p-type layer 17). The second cathode contact region 22 can have a p-type impurity concentration greater than a p-type impurity concentration of the upper p-type layer 31. The p-type impurity concentration of the second cathode contact region 22 can be, for example, between about 1.0×10¹⁶ cm⁻³ and about 5.0×10¹⁷ cm⁻³.

Referring to FIG. 3, the second cathode contact region 22 is exposed from the field insulating film 18 in the second opening portion 42. The second cathode contact region 22 has a quadrilateral annular shape matching the second opening portion 42. The second cathode contact region 22 includes a first side portion 22a and a second side portion 22b extending along the first direction X with a space in between. The second cathode contact region 22 further includes a third side portion 22c and a fourth side portion 22d connecting the first side portion 22a and the second side portion 22b. The third side portion 22c and the fourth side portion 22d extend along the second direction Y with a space in between. Referring to FIG. 6, a second width W₂ of the second cathode contact region 22 can be between about 0.6 μm and about 0.8 μm. The second width W₂ can be constant in an entire circumferential region of the second cathode contact region 22.

Referring to FIG. 2, FIG. 5 and FIG. 6, the third cathode contact region 23 is formed in a surface portion of the outer diffusion region 15B. The third cathode contact region 23 can have an n-type impurity concentration greater than an n-type impurity concentration of the outer diffusion region 15B. The n-type impurity concentration of the third cathode contact region 23 can be, for example, between about 1.0×10¹⁶ cm⁻³ and about 5.0×10¹⁷ cm⁻³.

Referring to FIG. 3, the third cathode contact region 23 is exposed from the field insulating film 18 in the third opening portion 43. The third cathode contact region 23 has a quadrilateral annular shape matching the third opening portion 43. The third cathode contact region 23 includes a first side portion 23a and a second side portion 23b extending along the first direction X with a space in between. The third cathode contact region 23 further includes a third side portion 23c and a fourth side portion 23d connecting the first side portion 23a and the second side portion 23b. The third side portion 23c and the fourth side portion 23d extend along the second direction Y with a space in between. Referring to FIG. 6, a third width W₃ of the third cathode contact region 23 can be between about 0.6 μm and about 0.8 μm. The third width W₃ can be constant in an entire circumferential region of the third cathode contact region 23.

Referring to FIG. 4, the gate electrode 19 is formed on the first surface 3 of the semiconductor chip 2. For the sake of clarity, in FIG. 4, the gate electrode 19 is indicated by shading lines. The gate electrode 19 can include, for example, a conductive material such as polycrystalline silicon or aluminum. The gate electrode 19 is formed to have an annular shape in the plan view. The gate electrode 19 can include a pair of first portions 51 facing each other in the second direction Y, and a second portion 52 connecting the pair of first portions 51. In the embodiment, the first portions 51 are formed to have linear shapes extending parallel to each other along the first direction X, and the second portion 52 is formed to have an arc shape expanding outward in the first direction X. An opening portion 50 is formed in a central portion of the gate electrode 19 defined by the pair of first portions 51 and the pair of second portions 52. The opening portion 50 is formed to have an ellipsoidal shape extending along the first direction X in the plan view. The opening portion 50 exposes a portion of the p-type well region 16. More specifically, the opening portion 50 exposes the anode contact region 20.

Referring to FIG. 4, a channel is formed in a region facing the gate electrode 19 in the p-type well region 16. Formation of the channel in the region is controlled by the gate electrode 19. A thickness of the gate electrode 19 can be, for example, between about 0.1 μm and about 0.4 μm.

Referring to FIG. 6, a gate insulating film 54 is formed between the gate electrode 19 and the first main surface 3. The gate insulating film 54 can be, for example, a SiO₂ film formed by thermal oxidizing the first main surface 3. A thickness of the gate insulating film 54 can be, for example, between about 0.2 nm and about 100 nm.

Referring to FIG. 6, the gate electrode 19 can integrally include an annular control portion 55 on the side (inside) of the opening portion 50, and an annular field plate portion 56 outside the control portion 55. The control portion 55 of the gate electrode 19 is separated by the gate insulating film 54 to sequentially cover the p-type well region 16 (the region in which the channel is formed) and the p-type layer 17 from the inside to the outside. On the p-type layer 17, the field plate portion 56 of the gate electrode 19 is formed on the field insulating film 18.

Referring to FIG. 6, a sidewall structure 57 is formed in a side portion of the gate electrode 19. The sidewall structure 57 is formed in both an inner side portion (a side portion of the opening portion 50) and an outer side portion of the gate electrode 19.

Referring to FIG. 6, the anode contact region 20 is formed in a surface portion of the p-type well region 16. The anode contact region 20 is a strip shape extending along the first direction X. The anode contact region 20 is a p-type impurity region.

Referring to FIG. 2, the anode contact region 20 includes a first side portion 20a and a second side portion 20b extending along the first direction X with a space in between. The anode contact region 20 further includes a third side portion 20c and a fourth side portion 20d connecting the first side portion 20a and the second side portion 20b. The third side portion 20c and the fourth side portion 20d are formed to have arc shapes expanding in the first direction X. All of the first side portion 20a to the fourth side portion 20d depart from a peripheral edge (the first peripheral edge 61 to the fourth peripheral edge 64) of the p-type well region 16 in the plan view. That is to say, in the surface portion of the p-type well region 16, the anode contact region 20 is formed to depart the peripheral edge (the first peripheral edge 61 to the fourth peripheral edge 64) of the p-type well region 16) toward inside.

Referring to FIG. 6, a fourth width W₄ of the anode contact region 20 in the second direction Y is between about 1.5 μm and about 2.0 μm. The fourth width W₄ is greater than any one of the first width W₁, the second width W₂ and the third width W₃ (W₄>W₁, W₄>W₂ and W₄>W₃). The fourth width W₄ can be constant in an entire region in the first direction X. The anode contact region 20 can be formed to have a quadrilateral shape extending longer in the first direction X in the plan view.

Referring to FIG. 3 and FIG. 6, in the surface portion of the first main surface 3, the anode contact region 20, the first cathode contact region 21, the second cathode contact region 22 and the third cathode contact region 23 are electrically separated by the field insulating film 18. In the surface portion of the first main surface 3, the first cathode contact region 21 surrounds the anode contact region 20. Referring to FIG. 6, a first space W₁₁ between the anode contact region 20 and the first cathode contact region 21 in the second direction Y is between about 1.0 μm and about 2.0 μm. The second cathode contact region 22 surrounds an outer periphery of the first cathode contact region 21. Referring to FIG. 6, a second space W₁₂ between the first cathode contact region 21 and the second cathode contact region 22 in the second direction Y is between about 1.0 μm and about 2.0 μm. The third cathode contact region 23 surrounds an outer periphery of the second cathode contact region 22. Referring to FIG. 6, a third space W₁₃ between the second cathode contact region 22 and the third cathode contact region 23 in the second direction Y is between about 1.0 μm and about 2.0 μm.

Referring to FIG. 6, the first space W₁₁ can be greater than the second space W₁₂ (W₁₁>W₁₂); the third space W₁₃ can be equal to the second space W₁₂ (W₁₃=W₁₂); or the third space W₁₃ can be greater than the second space W₁₂ (W₁₃>W₁₂), or can be less than the second space W₁₂ (W₁₃<W₁₂).

Referring to FIG. 5 and FIG. 6, the interlayer insulating film 24 is formed on the first main surface 3 of the semiconductor chip 2. The interlayer insulating film 24 covers the gate electrode 19. The interlayer insulation film 24 is formed of, for example, a SiO₂ or SiN₂. In this embodiment, the interlayer insulating film 24 is formed by a single film of SiO₂, but can be formed as multiple interlayer insulating films 24.

Referring to FIG. 6, the anode wiring 25 is formed on the interlayer insulating film 24. The anode wiring 25 is electrically connected to the anode contact region 20 via an anode contact 26. Referring to FIG. 6, the anode contact 26 is formed at a position overlapping the anode contact region 20 in the plan view to pass through the interlayer insulating film 24.

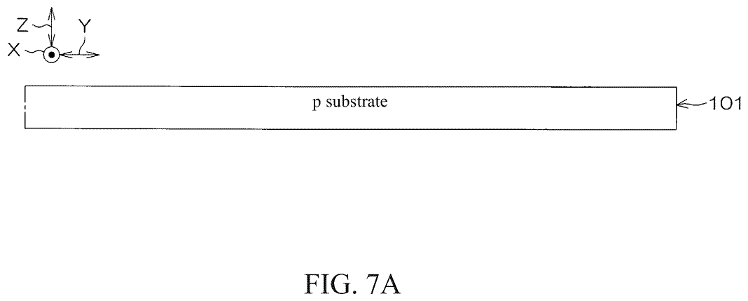

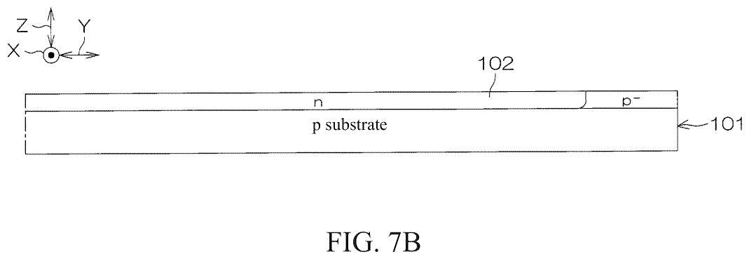

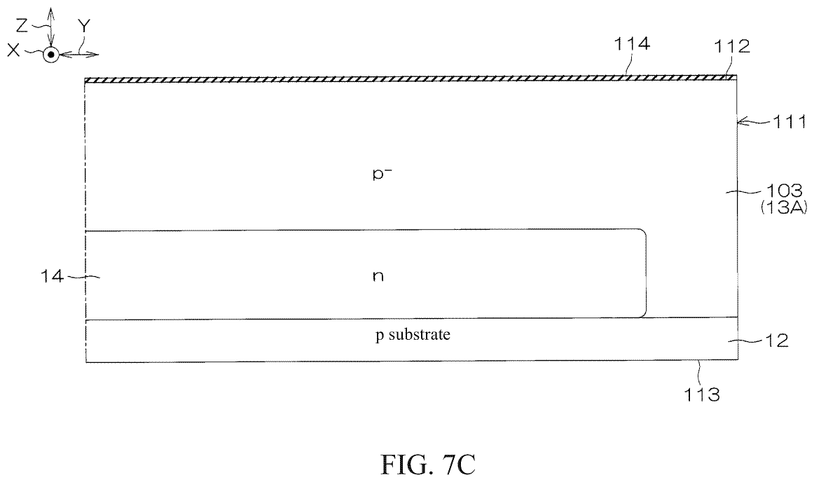

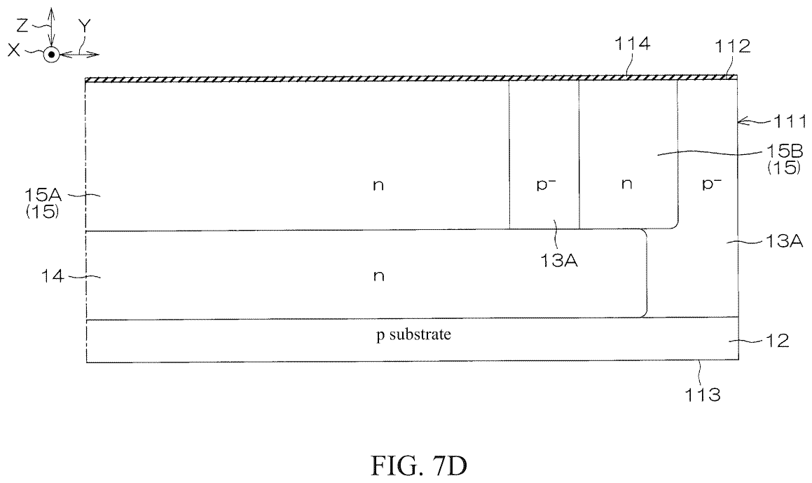

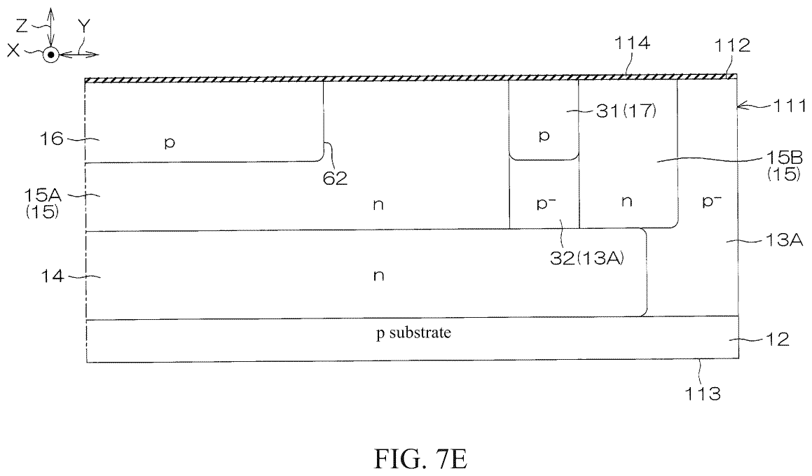

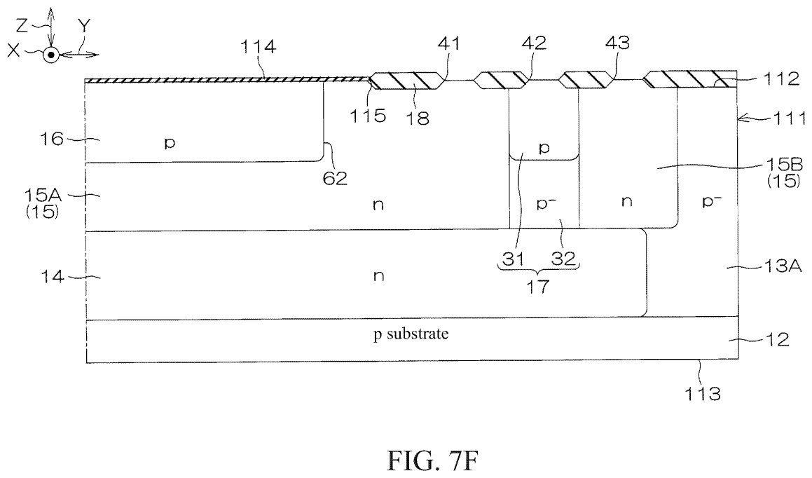

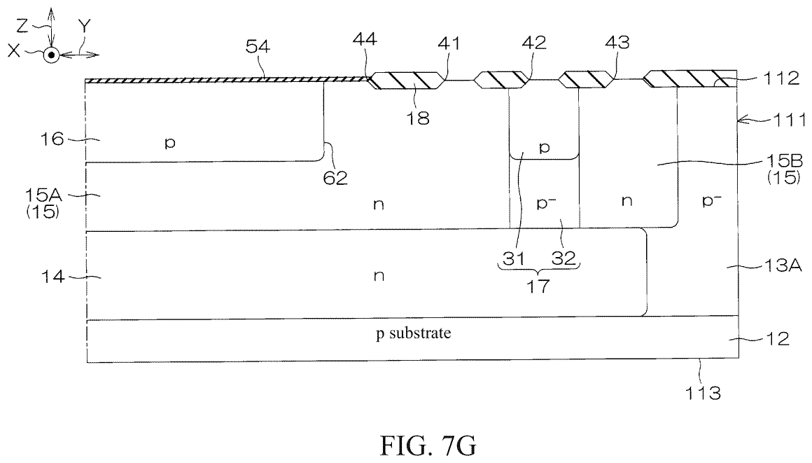

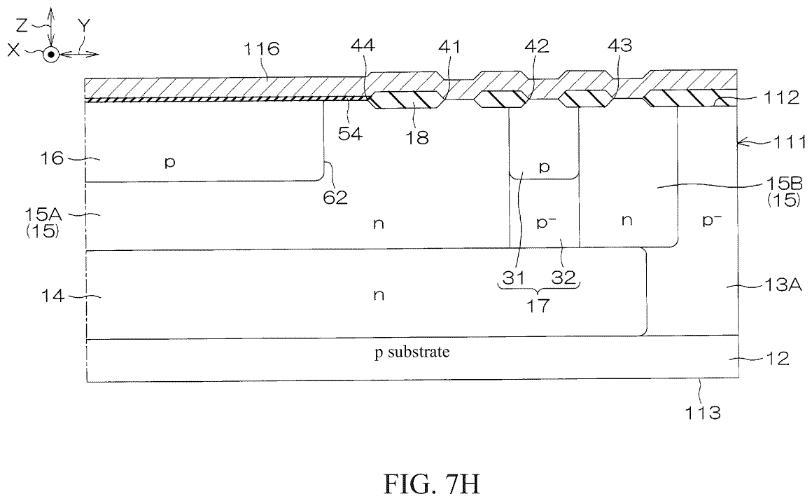

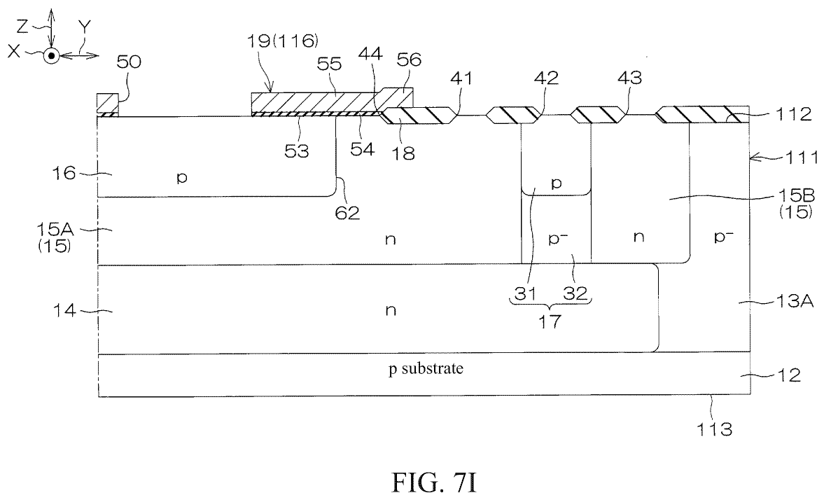

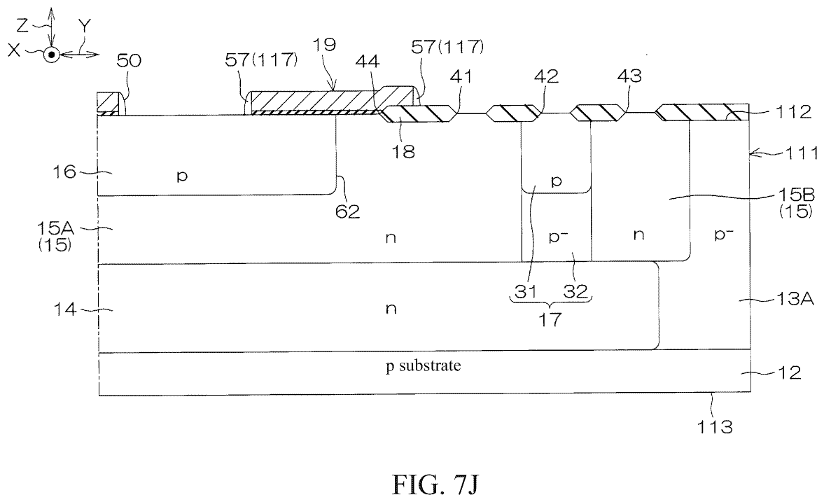

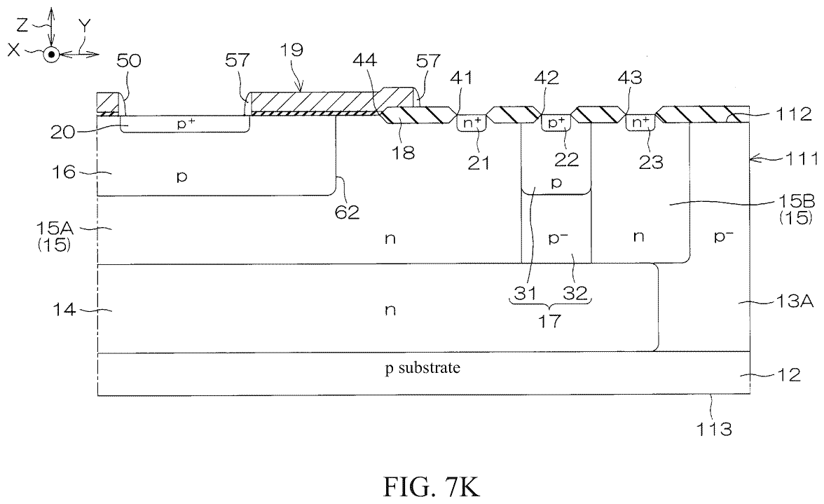

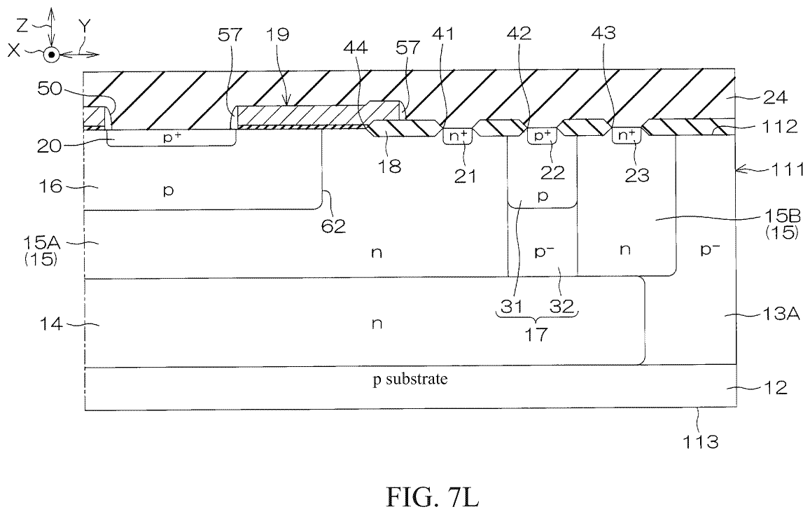

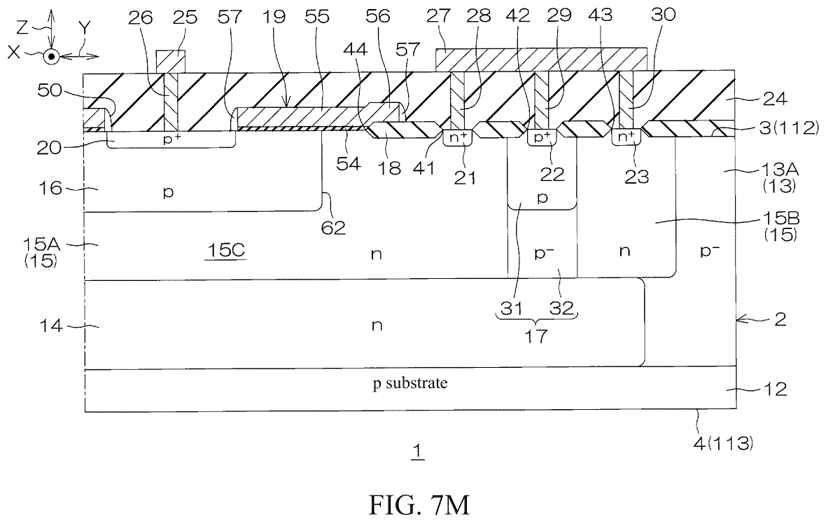

Referring to FIG. 6, the cathode wiring 27 is formed on the interlayer insulating film 24. The cathode wiring 27 is electrically connected to the first cathode contact region 21, the second cathode contact region 22 and the third cathode contact region 23 via a first cathode contact 28, a second cathode contact 29 and a third cathode contact 30, respectively. Referring to FIG. 4 and FIG. 7, the first cathode contact 28 is formed at a position overlapping the first cathode contact region 21 in the plan view to pass through the interlayer insulating film 24. The second cathode contact 29 is formed at a position overlapping the second cathode contact region 22 in the plan view to pass through the interlayer insulating film 24. The third cathode contact 30 is formed at a position overlapping the third cathode contact region 23 in the plan view to pass through the interlayer insulating film 24.

In this embodiment, the anode wiring 25 and the cathode wiring 27 are formed of aluminum (Al), but can also be formed of other conductive materials (for example, copper (Cu)). In this embodiment, the anode contact 26, the first cathode contact 28, the second cathode contact 29 and the third cathode contact 30 are formed of tungsten (W), but can also be formed of other conductive materials (for example, Al and Cu). At this point, a barrier film such as TiN can also be used.

Moreover, although omitted from the drawings, a gate contact mechanically and electrically connected to the gate electrode 19 is buried in the interlayer insulating film 24. The gate contact is electrically insulated from the anode contact 26, the first cathode contact 28, the second cathode contact 29 and the third cathode contact 30.

A pn junction diode Di1 (referring to FIG. 5) is formed by the p-type well region 17 and an inner diffusion region 15A adjacent to the p-type well region 16. When a forward bias is applied between the anode wiring 25 and the cathode wiring 27, a positive voltage is applied to the p-type well region 16 and a negative voltage is applied to the inner diffusion region 15A. In this case, a current flows from the anode contact region 20 through the pn junction diode Di1 to the first cathode contact region 21. Accordingly, in the surface portion of the first main surface 3, a current path from the anode contact region 20 through the p-type well region 16 and the inner diffusion region 15A to the first cathode contact region 21 is formed.

In the diode 10, a vertical parasitic pnp transistor is formed by the p-type well region 16, the p-type semiconductor substrate 12 and an n-type transistor (the n-type diffusion region 15 and the n-type buried layer 14) between the two above. Moreover, in the diode 10, a horizontal parasitic pnp transistor is formed by the p-type well region 16, the p-type layer 17 and the inner diffusion region 15A between the two above. In general, there is a concern for leakage current due to these pnp transistors.

According to this embodiment, the impurity concentration of the n-type buried layer 14 is a relatively high concentration (between about 1.0×10¹³ cm⁻³ and about 5.0×10¹³ cm⁻³). Thus, when a forward bias is applied between the anode wiring 25 and the cathode wiring 27, the amount current flowing from the inner diffusion region 15A to the n-type buried layer 14 can be suppressed or prevented. Thus, leakage current caused by the vertical parasitic pnp transistor can be suppressed or prevented.

Moreover, in this embodiment, the n-type diffusion region 15 is divided by the p-type layer 17 outside the first cathode contact region 21. Thus, a current flowing from the anode contact region 20 to the first cathode contact region 21 can be suppressed or prevented from leaking from a region outside the anode contact region 20 to the outside. As a result, leakage current caused by the horizontal parasitic pnp transistor can be suppressed or prevented.

Moreover, since the n-type buried layer 14 having an impurity concentration greater than that of the n-type diffusion region 15 is formed below the n-type diffusion region 15, a current flowing from the anode contact region 20 to the first cathode contact region 21 can also be suppressed or prevented from leaking from the bottom of the n-type diffusion region 15 to below.

Moreover, a pnp transistor Tr (referring to FIG. 5) is formed in the diode 10. The pnp transistor Tr is formed by the p-type well region 16, the p-type layer 17 and the inner diffusion region 15A sandwiched between the two above. In addition, the second cathode contact region 22 formed in the p-type layer 17 is connected to the cathode wiring 27. Thus, a current flowing to the pnp transistor Tr is recollected to the cathode wiring 27 via the second cathode contact region 22. Accordingly, leakage current caused by the horizontal parasitic pnp transistor can be more effectively suppressed or prevented.

Moreover, a pn junction diode Di2 (referring to FIG. 5) is formed by the p-type layer 17 and the outer diffusion region 15B adjacent to the p-type layer 17. When a forward bias is applied between the anode wiring 25 and the cathode wiring 27, a negative voltage is further applied to the outer diffusion region 15B in addition to the inner diffusion region 15A.

When a forward bias is applied between the anode wiring 25 and the cathode wiring 27, as described above, a current path from the anode contact region 20 through the p-type well region 16 and the inner diffusion region 15A to the first cathode contact region 21 is formed. In this case, even if a current leaks from the p-type layer 17 to the outside, the leakage current can return to the cathode wiring 27 via the pn junction diode Di2 and the first cathode contact region 21.

With the configuration of this embodiment, leakage current can be reduced by improving pn junction separation without involving a physical module (for example, silicon on insulator (SOI) for reducing such leakage current.

FIG. 7A to FIG. 7M show part of manufacturing step for the semiconductor device 1. FIG. 7A to FIG. 7M correspond to FIG. 6.

First of all, referring to FIG. 7A, a piece of semiconductor wafer 101 is prepared. The semiconductor wafer 101 becomes a base of the semiconductor chip 2 (referring to FIG. 5 and FIG. 6). The semiconductor wafer 101 is p-type wafer. The semiconductor wafer 101 corresponds to the semiconductor substrate 12 of the semiconductor device 1 (referring to FIG. 5 and FIG. 6).

Next, referring to FIG. 7B, a hard mask (not shown) having an opening corresponding to a region in which the n-type buried layer 14 (referring to FIG. 5 and FIG. 6) is formed is prepared, and an n-type impurity is selectively introduced to a surface portion of the semiconductor wafer 101 via the hard mask. Accordingly, an introduced portion 102 is formed in the surface portion of the semiconductor wafer 101. The n-type impurity can be, for example, phosphorous (P) or arsine (As).

Next, referring to FIG. 7C, an epitaxial layer 103 is formed by epitaxially growing silicon of the semiconductor wafer 101. By forming the epitaxial layer 103, a semiconductor wafer structure 111 including a p-type epitaxial layer 13A is formed. The epitaxial layer 103 corresponds to the p-type epitaxial layer 13A. The n-type buried layer 14 is formed by diffusing the n-type impurity introduced to the introduced portion 102 of a main surface of the semiconductor wafer 101 to the p-type epitaxial layer 103. The semiconductor wafer structure 111 includes a first water main surface 112 on one side and a second wafer main surface 113 on the other side. The first wafer main surface 112 and the second wafer main surface 44 respectively correspond to the first main surface 3 and the second main surface 4 of the semiconductor chip 2 (referring to FIG. 5 and FIG. 6). Next, a sacrificial insulating film 114 is formed on the first wafer main surface 112. The sacrificial insulating film 114 can be, for example, a SiO₂ film formed by thermal oxidizing a surface portion of the first main surface 112 into a film.

Next, referring to FIG. 7D, a hard mask (not shown) having an opening corresponding to a region in which the n-type diffusion region 15 (referring to FIG. 5 and FIG. 6) is formed is prepared, and an n-type impurity is selectively introduced to the surface portion of the semiconductor wafer 101 via the hard mask. Next, the introduced n-type impurity is diffused by a thermal treatment performed on the semiconductor wafer structure 111. The n-type diffusion region 15 is formed accordingly. The n-type diffusion region 15 includes the inner diffusion region 15A and the outer diffusion region 15B.

Next, referring to FIG. 7E, a hard mask (not shown) having an opening corresponding to a region in which the p-type well region 16 and the upper p-type layer 31 (referring to FIG. 5 and FIG. 6) are formed is prepared, and a p-type impurity is selectively introduced to the surface portion of the semiconductor wafer 101 via the hard mask. Next, the introduced p-type impurity is diffused by a thermal treatment performed on the semiconductor wafer structure 111. The upper p-type layer 31 and the p-type layer 17 are formed accordingly. Moreover, in the first direction X and the second direction Y, a region in which the upper p-type layer 31 is not formed in the p-type epitaxial layer between the inner diffusion region 15A and the outer diffusion region 15B becomes the lower p-type layer 32.

An order of forming the n-type diffusion region 15, the p-type well region 16 and the upper p-type layer 31 can be modified as appropriate. For example, the p-type well region 16 and the upper p-type layer 31 can be formed first, and the n-type diffusion region 15 is then formed. Moreover, instead of forming the p-type well region 16 and the upper p-type layer 31 simultaneously, one between the p-type well region 16 and the upper p-type layer 3 is formed first, and the other between the p-type well region 16 and the upper p-type layer 3 is then formed.

Next, referring to FIG. 7F, a hard mask (not shown) is formed on the sacrificial insulating film 114, and the sacrificial insulating film 114 is selectively removed by etching using the mask to accordingly form an opening 115. Next, the field insulating film 18 is formed by thermal oxidizing the surface portion of the first wafer main surface 112 exposed from the opening 115 of the sacrificial insulating film 114. Then, the sacrificial insulating film 114 is removed.

Next, referring to FIG. 7C, the gate insulating film 54 is formed on the first wafer main surface 112. The gate insulating film 54 can be, for example, a SiO₂ film formed by thermal oxidizing the surface portion of the first main surface 112 exposed from the first opening portion 41, the second opening portion 42, the third opening portion 43 and the fourth opening portion 44 into a film.

Next, referring to FIG. 7H, a base electrode to form a base of the gate electrode 19 (referring to FIG. 5 and FIG. 6) is formed on the first wafer main surface 112 to cover the gate insulating film 54 and the field insulating film 18. In this embodiment, the base electrode 116 includes conductive polycrystalline silicon. The base electrode 116 can be formed by means of chemical vapor deposition (CVD), for example.

Next, referring to FIG. 7I, a useless part of the base electrode 116 is removed by etching using a mask (not shown) having a predetermined pattern. The gate electrode 19 is formed accordingly. The etching can be, for example, reactive ion etching (RIE) or wet etching. Then, the gate insulating film 54 exposed from the gate electrode 19 is removed, the p-type well region 16 becomes exposed from the opening portion 50, and the inner diffusion region 15A (the n-type diffusion region 15) becomes exposed from the first opening portion 41 of the field insulating film 18.

Next, referring to FIG. 7J, a base insulating film 117 to become a base of the sidewall structure 57 (referring to FIG. 6) is sequentially formed on the first wafer main surface 112. The base insulating film 117 can be formed by means of CVD, for example. Next, a useless part of the base insulating film 117 is removed by etching. Accordingly, the sidewall structure 57 is formed by the base insulating film 117 residual on the inner side portion and the outer side portion of the gate electrode 19.

Next, referring to FIG. 7K, the anode contact region 20 and the second cathode contact region 22 respectively form the surface portion of the p-type well region 16 and the surface portion (that is, the surface portion of the p-type layer 17) of the upper p-type layer 31. Moreover, the first cathode contact region 21 and the third cathode contact region 23 respectively form the surface portion of the inner diffusion region 15A (the n-type diffusion region 15) and the surface portion of the outer diffusion region 15B (the n-type diffusion region 15). In this embodiment, the anode contact region is formed by injecting a p-type impurity into the surface portion of the p-type well region 16 by means of ion implantation using the sidewall structure 57 as a hard mask. That is to say, the anode contact region 20 is formed in a self-aligned manner with respect to the periphery of the sidewall structure 57 of the gate electrode 17. The first cathode contact region 21 and the third cathode contact region 23 are formed by injecting an n-type impurity respectively into the surface portions of the inner diffusion region 15A and the outer diffusion region 15B by means of ion implantation using the field insulating film 18 as a hard mask. That is to say, the first cathode contact region 21 and the third cathode contact region 23 are formed in a self-aligned manner with respect to the peripheries of the first opening portion 41 and the third opening portion 43 of the field insulating film 18. The second cathode contact region 22 is formed by injecting a p-type impurity into the surface portion of the p-type well region 31 by means of ion implantation using the field insulating film 18 as a hard mask. That is to say, the second cathode contact region 22 is formed in a self-aligned manner with respect to the periphery of the second opening portion 42 of the field insulating film 18.

Next, referring to FIG. 7L, the interlayer insulating film 24 is formed on the first wafer main surface 112. The interlayer insulating film 24 can be formed by means of CVD, for example.

Next, referring to FIG. 7M, the anode contact 26, the first cathode contact 28, the second cathode contact 29 and the third cathode contact 30 are formed on the interlayer insulating film 24 by etching using a hard mask (not shown) having a predetermined pattern, formation of a metal film by means of CVD and etching a useless metal film. Next, the anode wiring 25 and the cathode wiring 27 are formed by patterning a base wiring that is to become a base of multiple wirings formed on the interlayer insulating film 24. Then, the semiconductor wafer structure 111 is dissected into multiple semiconductor chips 2. The semiconductor device 1 is manufactured by the steps above.

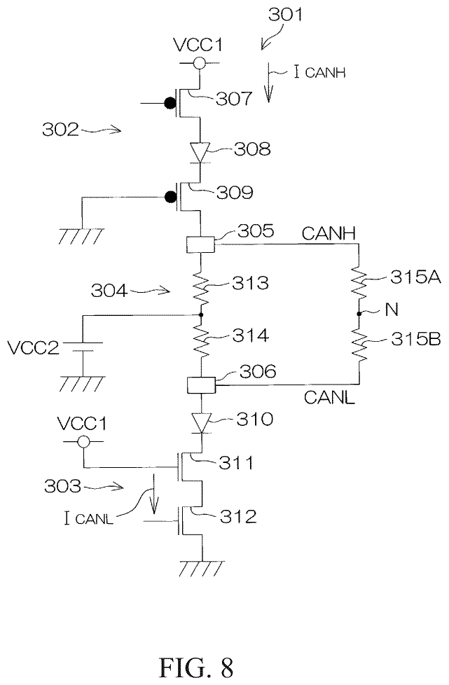

FIG. 8 shows a circuit diagram of a configuration of a signal output circuit 301 applying the diode 10 in the semiconductor device 1. The signal output circuit 301 is, for example, a circuit used for an on-vehicle network, that is, controller area network (CAN). The signal output circuit 301 includes a high-side output section 302, a low-side output section 303, a resistor dividing circuit 304, a high-side output terminal 305 and a low-side output terminal 306.

The high-side output section 302 includes a driving transistor 307, a first diode 308 and a protection transistor 309. The first diode 308 is connected in series to the driving transistor 307. The protection transistor 309 is connected in series to the first diode 308. In this embodiment, the driving transistor 307 and the protection transistor 309 include p-type MOSFETs. The first diode 308 functions as a backflow preventing circuit. The first diode 308 is implemented by the diode 10 of the semiconductor device 1. A source of the driving transistor 307 connected to a first power supply VCC1. A drain of the driving transistor 307 is connected to an anode of the first diode 308. A cathode of the first diode 308 is connected to a source of the protection transistor 309. A drain of the protection transistor 309 is connected to the high-side output terminal 305. A gate of the protection transistor 309 is grounded.

The low-side output section 303 includes a second diode 310, a protection diode 311 and a driving transistor 312. The second diode 310 is connected in series to the protection transistor 311. The protection transistor 311 is connected in series to the second diode 310. The driving transistor 312 is connected in series to the protection transistor 311. In this embodiment, the protection transistor 311 and the driving transistor 312 include n-type MOSFETs. An anode of the second diode 310 is connected to the low-side output terminal 306. A cathode of the second diode 310 is connected to a drain of the protection transistor 311. A gate of the protection transistor 311 is connected to the first power supply VCC1. A source of the protection transistor 311 is connected to a drain of the driving transistor 312. A source of the driving transistor 312 is grounded.

The resistor dividing circuit 304 includes a first resistor 313 and a second resistor 314. One end of the first resistor 313 is connected to the high-side output terminal 305. The other end of the first resistor 313 is connected to one end of the second resistor 314. The other end of the second resistor 314 is grounded. A connection node between the first resistor 313 and the second resistor 314 is connected to a second power supply VCC2.

The high-side output terminal 305 is connected to a first bus. The low-side output terminal 306 is connected to a second bus. A load resistor is connected between the first bus and the second bus. The load resistor includes a high-side load resistor 315A and a low-side load resistor 315B connected in series by a connection node N. The load resistor 315A and the load resistor 315B have the same resistance value as each other.

For example, the first power supply VCC1 is set to 5 V. At this point, the connection node N is set to have a midpoint voltage, that is, 2.5 V. Since currents flowing through the first resistor 313 and the second resistor 314 are common, a voltage drop generated by each of the first resistor 313 and the second resistor 314 is also the same, a high-side signal CANH generated in the high-side output terminal 305 has a voltage higher than the voltage (the midpoint voltage) of the connection node N by the voltage drop, and a low-side signal CANL generated in the low-side output terminal 306 has a voltage lower than the voltage (the midpoint voltage) of the connection node N by the voltage drop. The midpoint voltage can also be referred to as a common voltage.

A control signal is provided to the gate of the driving transistor 307. An inverted signal of the control signal is provided to the gate of the driving transistor 312. When the control signal is at a low level (L), both of the driving transistors 307 and 312 are turned on. Accordingly, the high-side signal CANH in 3.5 V (a standard value) is output to the high-side output terminal 305, and the low-side signal CANL in 1.5 V (a standard value) is output to the low-side output terminal 306 (a dominant state). On the other hand, when the control signal is at a high level (H), both of the driving transistors 307 and 312 are turned off. Accordingly, the high-side signal CANH in 2.5 V (a standard value) is output to the high-side output terminal 305, and the low-side signal CANL in 2.5 V (a standard value) is output to the low-side output terminal 306 (a recessive state).

In this embodiment, the first diode 308 of the high-side output section 203 and the second diode 310 of the low-side output section 303 are implemented by the diode 10 of the semiconductor device 1.

Assuming that the first diode 308 and the second diode 310 are implemented by other diodes (diodes with insufficient leakage reduction) instead of the diode 10 of the semiconductor device 1, issues such as those below are generated. That is to say, due to the leakage current in the first diode 308 and the second diode 310, a value of a current I_{CANL} flowing through the low-side output section 303 is higher than a value of a current I_{CANH} flowing through the high-side output section 302 (I_{CANL}<I_{CANH}). In this case, there is a concern for a decreased voltage (the midpoint voltage) at the connection node N. When the voltage (the midpoint voltage) decreases, there is a concern that the voltages of the high-side signal CANH and the low-side signal CANL decrease from desired voltages. To achieve good CAN communication, the leakage current in the first diode 308 and the second diode 310 needs to be sufficiently reduced. Moreover, the value of the current I_{CANL} is preferably to be as close to the value of the current I_{CANL} as possible (I_{CANL}=I_{CANH}).

In this embodiment, the first diode 308 and the second diode 310 are implemented by the diode 10 of the semiconductor device 1. Thus, the leakage current in the first diode 308 and the second diode 310 can be sufficiently reduced, and the value of the current I_{CANL} can become as close to the value of the current I_{CANH} as possible.

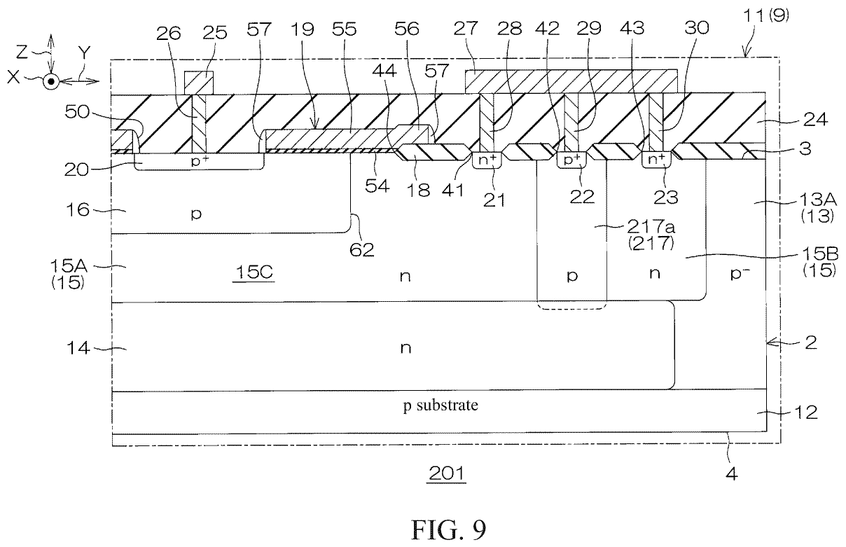

FIG. 9 shows a diagram for illustrating effects of the semiconductor device 1.

TABLE 1

| | | Diode 10 of semiconductor |
|---|---|---|
| | Reference example | device 1 |
| Ratio of leakage (%) | 8.79 (%) | 0.55 (%) |

In Table-1, ratios of leakage (value of leakage current (I_{CANL}−I_{CANH})/current value (I_{CANH}) current in the semiconductor device 1 and a semiconductor device of the reference example are compared. The semiconductor device of the reference example differs from the semiconductor device 1 in that, the bottom of the p-type layer 17 does not reach the n-type buried layer 14 (that is, the lower p-type layer 32 is not provided). Other details of the semiconductor device of the reference example are the same as those of the semiconductor device 1.

It is seen from Table-1 that, comparing the semiconductor device 1 with the semiconductor device of the reference example, leakage current can be reduced.

FIG. 10 shows a schematic cross-sectional diagram of a semiconductor device 201 according to a second embodiment of the present disclosure, and is a diagram corresponding to FIG. 7. In FIG. 10, the same structures up to this point of description are denoted by the same reference numerals and symbols, and associated details are omitted herein.

The semiconductor device 201 differs from the semiconductor device 1 of the first embodiment in that, a p-type layer 217 is provided in substitution for the p-type layer 17. The p-type layer 217 differs from the p-type layer 17 of the first embodiment in that, the p-type layer 217 is formed merely by a p-type diffusion layer 217a. A bottom of the p-type layer 217a extends to the n-type buried layer in the depth direction.

The semiconductor device 201 of the second embodiment of the present disclosure achieves the same effects as those described in the first embodiment.

Moreover, in the semiconductor device 1 and the semiconductor device 201, the first cathode contact region 21, the second cathode contact region 22 and the third cathode contact region 23 having quadrilateral annular shapes are given for illustration; however, the cathode contact regions 21 to 23 can also be strip shapes extending longer in the first direction X. In this case, each of the cathode contact regions 21 to 23 is formed in pair spaced by the anode contact region 20.

In the embodiments, examples in which the first conductivity type is the p type and the second conductivity type is the n type are described; however, the first conductivity type can also be the n type and the second conductivity type can also be the p type. In this case, a specific configuration can be arrived at by substituting an n-type region for a p-type region and substituting a p-type region for an n-type region in the description and the accompanying drawings.

In the embodiments, the signal output circuit 301 used as a type of on-vehicle network, that is, a CAN circuit, is given for illustration. However, the diodes 308 and 310 (that is, the diode 10 of the semiconductor device 1) of the signal output circuit 301, in addition to being applied as a signal output circuit used in CAN, can also be applied as a signal output circuit in other on-vehicle networks such as a local interconnect network (LIN) and FlexRay. As a matter of course, the diode 10 of the semiconductor device 1 can also be applied as a diode for an on-vehicle integrated circuit (IC) or a diode for direct-current/direct-current (DC/DC) conversion.

The embodiments of the present disclosure described above are examples in all aspects and are not to be interpreted in a restrictive manner, but are intended to encompass modifications in all aspects.

The features given in the note below can be extracted from the detailed description and the drawings of the present detailed description. In the description below, alphabets and numerals given in the parentheses represent the corresponding constituents in the embodiments, and are intended to limit the scope of the clauses to the subjects of the embodiments.

### [Note 1-1]

A semiconductor device (1, 201), comprising:
a semiconductor substrate (12) of a first conductivity type;
a diffusion region (15) of a second conductivity type, selectively formed in a surface portion of the semiconductor substrate (12);
a buried layer (14) of the second conductivity type, formed between the semiconductor substrate (12) and the diffusion region (15) of the second conductivity type, and having an impurity concentration greater than an impurity concentration of the diffusion region (15) of the second conductivity type;
an anode contact region (20) of the first conductive type, formed in a surface portion of a main surface (3) of the semiconductor substrate;
a first cathode contact region (21) of the second conductivity type, formed in a surface portion of the diffusion region (15) of the second conductivity type and the surface portion of the main surface (3);
a layer (17, 217) of the first conductive type, extending from the main surface (3) of the semiconductor substrate (12) along a depth direction outside the first cathode contact region (21) to reach the buried layer (14) of the second conductivity type, and dividing the diffusion region (15) of the second conductivity type along a direction of the main surface (3).

According to the configuration above, a current path from the anode contact region (20) to the first cathode contact region (21) is formed in the diffusion region (15) of the second conductivity type. Moreover, the diffusion region (15) of the second conductivity type is divided by the layer (17, 217) of the first conductive type outside the first cathode contact region (21). Thus, a current flowing from the anode contact region (20) to the first cathode contact region (21) can be suppressed or prevented from flowing from a region outside the first cathode contact region (21) to the outside.

Moreover, since the buried layer (14) of the second conductivity type having an impurity concentration greater than the impurity concentration of the diffusion region (15) of the second conductivity type is formed below the impurity concentration of the diffusion region (15) of the second conductivity type, the current flowing from the anode contact region (20) to the first cathode contact region (21) can be suppressed or prevented from flowing from a bottom of the diffusion region (15) of the second conductivity type to below.

Accordingly, the semiconductor device (1, 201) having a diode capable of reducing leakage current can be provided.

### [Note 1-2]

The semiconductor device (1, 201) according to note 1-1, wherein the layer (17, 217) of the first conductive type has an annular shape in a plan view and divides the diffusion region (15) of the second conductive type in both a first direction (X) along the main surface (3) and a second direction (Y) along the main surface (3) and intersecting the first direction (X).

### [Note 1-3]

The semiconductor device (1, 201) according to note 1-1 or 1-2, further comprising:
a second cathode contact region (22) of the first conductivity type, formed outside the first cathode contact region (21) in the surface portion of the main surface (3),
wherein the layer (7, 217) of the first conductive type is electrically connected to the second cathode contact region (22).

### [Note 1-4]

The semiconductor device (1, 201) according to notes 1-1 to 1-3, wherein the second cathode contact region (22) is formed in a surface portion of the layer (17, 217) of the first conductive type.

### [Note 1-5]

The semiconductor device (1, 201) according to note 1-3 or 1-4, further comprising:
a third cathode contact region (23) of the second conductivity type, formed outside the second cathode contact region (22) in the surface portion of the main surface (3),
wherein the diffusion region (15) of the second conductive type includes an outer diffusion region (15B) formed outside the layer (17, 217) of the first conductive type, and
the outer diffusion region (15B) is electrically connected to the third cathode contact region (23).

### [Note 1-6]

The semiconductor device (1, 201) according to note 1-5, wherein the third cathode contact region (23) is formed in a surface portion of the outer diffusion region (15B).

### [Note 1-7]

The semiconductor device (1) according to any one of notes 1-1 to 1-6, wherein the layer (17) of the first conductive type includes: an upper layer (31) of the first conductive type; and a lower layer (32) of the first conductive type, formed adjacent to and below the upper layer (31) of the first conductive type, and having an impurity concentration different from an impurity concentration of the upper layer (31) of the first conductive type.

### [Note 1-8]

The semiconductor device (1) according to note 1-7, wherein the impurity concentration of the upper layer (31) of the first conductivity type is greater than the impurity concentration of the lower layer (32) of the first conductivity type.

### [Note 1-9]

The semiconductor device (1) according to note 1-8, wherein the upper layer (31) of the first conductive type includes a diffusion layer of the first conductive type including a diffusion layer, and
the lower layer (32) of the first conductive type includes an epitaxial layer of the first conductive type including an epitaxial layer.

### [Note 1-10]

The semiconductor device (1) according to any one of notes 1-7 to 1-9, further comprising:
a well region (16) of the first conductivity-type, formed adjacent to the diffusion region (15) of the second conductivity type and in the surface portion of the main surface (3), wherein the anode contact region (20) is formed at the surface portion and within the well region of the first conductivity type (16), and
a first depth (D₁) of a bottom of the upper layer (31) of the first conductivity type is equal to a second depth (D₂) of a bottom of the well region (16) of the first conductivity type.

### [Note 1-11]

The semiconductor device (201) according to any one of notes 1-1 to 1-10, wherein the layer (217) of the first conductive type includes a diffusion layer (217a) of the first conductive type including a diffusion layer, and a bottom of the diffusion layer (217a) of the first conductive type extends from the main surface along the depth direction to reach the buried layer (14) of the second conductive type.

### [Note 1-12]

The semiconductor device (1, 201) according to any one of notes 1-1 to 1-10, wherein the anode contact region (20) and the first cathode contact region (21) are have a strip shape and extend in a first direction (X) along the main surface (3), and a width (W₄) of the anode contact region (20) in a second direction (Y) along the main surface (3) and intersecting the first direction (X) is greater than a width (W₁) of the first cathode contact region (21) in the second direction (Y).

### [Note 1-13]

The semiconductor device (1, 201) according to any one of notes 1-1 to 1-12, further comprising:
a well region (16) of the first conductive type, formed adjacent to the diffusion region (15) of the second conductive type in the surface portion of the main surface (3),
wherein the diffusion region (15) of the second conductivity type includes a lower diffusion region (15C) vertically sandwiched between the buried layer (14) of the second conductivity type and the well region (16) of the first conductivity type.

### [Note 1-14]

The semiconductor device (1, 201) according to any one of notes 1-1 to 1-13, wherein an impurity concentration of the buried layer of the second conductive type is 10 times greater than an impurity concentration of the diffusion region of the second conductive type.

### [Note 1-15]

The semiconductor device (1, 201) according to any one of notes 1-1 to 1-14, wherein the first conductivity type is p type, and the second conductivity type is n type.

1. A semiconductor device, comprising:
a semiconductor substrate of a first conductivity type;
a diffusion region of a second conductivity type, selectively formed in a surface portion of the semiconductor substrate;
a buried layer of the second conductivity type,
formed between the semiconductor substrate and the diffusion region of the second conductivity type, and
having an impurity concentration greater than an impurity concentration of the diffusion region of the second conductivity type;
an anode contact region of the first conductive type, formed in a surface portion of a main surface of the semiconductor substrate;
a first cathode contact region of the second conductivity type, formed in a surface portion of the diffusion region of the second conductivity type;
a layer of the first conductive type,
extending from the main surface of the semiconductor substrate along a depth direction outside the first cathode contact region to reach the buried layer of the second conductivity type, and
dividing the diffusion region of the second conductivity type along a direction of the main surface.

2. The semiconductor device of claim 1, wherein the layer of the first conductive type is in annular shape in a plan view and divides the diffusion region of the second conductive type in both a first direction along the main surface and a second direction along the main surface and intersecting the first direction.

3. The semiconductor device of claim 1, further comprising:
a second cathode contact region of the first conductivity type, formed outside the first cathode contact region in the surface portion of the main surface, wherein
the layer of the first conductive type is electrically connected to the second cathode contact region.

4. The semiconductor device of claim 3, wherein the second cathode contact region is formed in a surface portion of the layer of the first conductive type.

5. The semiconductor device of claim 3, further comprising:
a third cathode contact region of the second conductivity type, formed outside the second cathode contact region in the surface portion of the main surface, wherein
the diffusion region of the second conductive type includes an outer diffusion region formed outside the layer of the first conductive type, and
the outer diffusion region is electrically connected to the third cathode contact region.

6. The semiconductor device of claim 5, wherein the third cathode contact region is formed in a surface portion of the outer diffusion region.

7. The semiconductor device of claim 1, wherein the layer of the first conductive type includes:
an upper layer of the first conductive type; and
a lower layer of the first conductive type,
formed adjacent to and below the upper layer of the first conductive type, and
having an impurity concentration different from an impurity concentration of the upper layer of the first conductive type.

8. The semiconductor device of claim 2, wherein the layer of the first conductive type includes:
an upper layer of the first conductive type; and
a lower layer of the first conductive type,
formed adjacent to and below the upper layer of the first conductive type, and
having an impurity concentration different from an impurity concentration of the upper layer of the first conductive type.

9. The semiconductor device of claim 7, wherein the impurity concentration of the upper layer of the first conductivity type is greater than the impurity concentration of the lower layer of the first conductivity type.

10. The semiconductor device of claim 9, wherein
the upper layer of the first conductive type includes a diffusion layer of the first conductive type including a diffusion layer, and
the lower layer of the first conductive type includes an epitaxial layer of the first conductive type including an epitaxial layer.

11. The semiconductor device of claim 10, further comprising:
a well region of the first-conductivity-type, formed adjacent to the diffusion region of the second conductivity type and in the surface portion of the main surface, wherein the anode contact region is formed at the surface portion and within the well region of the first conductivity type, and
a first depth of a bottom of the upper layer of the first conductivity type is equal to a second depth of a bottom of the well region of the first conductivity type.

12. The semiconductor device of claim 1, wherein
the layer of the first conductive type includes a diffusion layer of the first conductive type including a diffusion layer, and
a bottom of the diffusion layer of the first conductive type extends from the main surface along the depth direction to reach the buried layer of the second conductive type.

13. The semiconductor device of claim 2, wherein
the layer of the first conductive type includes a diffusion layer of the first conductive type including a diffusion layer, and
a bottom of the diffusion layer of the first conductive type extends from the main surface along the depth direction to reach the buried layer of the second conductive type.

14. The semiconductor device of claim 1, wherein
the anode contact region and the first cathode contact region have a strip shape and extend in a first direction along the main surface, and
a width of the anode contact region in a second direction along the main surface and intersecting the first direction is greater than a width of the first cathode contact region in the second direction.

15. The semiconductor device of claim 2, wherein
the anode contact region and the first cathode contact region have a strip shape and extend in a first direction along the main surface, and
a width of the anode contact region in a second direction along the main surface and intersecting the first direction is greater than a width of the first cathode contact region in the second direction.

16. The semiconductor device of claim 1, further comprising:
a well region of the first conductive type, formed adjacent to the diffusion region of the second conductive type in the surface portion of the main surface, wherein
the diffusion region of the second conductivity type includes a lower diffusion region vertically sandwiched between the buried layer of the second conductivity type and the well region of the first conductivity type.

17. The semiconductor device of claim 2, further comprising:
a well region of the first conductive type, formed adjacent to the diffusion region of the second conductive type in the surface portion of the main surface, wherein
the diffusion region of the second conductivity type includes a lower diffusion region vertically sandwiched between the buried layer of the second conductivity type and the well region of the first conductivity type.

18. The semiconductor device of claim 1, wherein an impurity concentration of the buried layer of the second conductive type is 10 times greater than an impurity concentration of the diffusion region of the second conductive type.

19. The semiconductor device of claim 2, wherein an impurity concentration of the buried layer of the second conductive type is 10 times greater than an impurity concentration of the diffusion region of the second conductive type.

20. The semiconductor device of claim 1, wherein the first conductivity type is p type, and the second conductivity type is n type.
